(19) United States
(12) Patent Application Publication
(10) Pub. No.: US 2009/0191691 A1
(43) Pub. Date: Jul. 30, 2009

(54) Method for singulating semiconductor devices

(75) Inventor: Chien-Hung Chen, Hsinchu (TW)

Correspondence Address: Joe McKinney Muncy, PO Box 1364, Fairfax, VA, 22038-1364, US

(73) Assignee: POWERTECH TECHNOLOGY INC.

(21) Appl. No.: 12/010,723

(22) Filed: Jan. 29, 2008

(51) Int. Cl. H01L 21/304

(52) U.S. Cl. 438/462; 257/E21.238

(57) ABSTRACT

Disclosed is a method for singulating semiconductor devices. The substrate has a plurality of scribe lines between the substrate units. A protecting film is provided having a patterned adhesive layer formed thereon corresponding to the scribe lines. The protecting film is attached and aligned to the substrate in a manner that the patterned adhesive layer adheres to the scribe lines without covering the substrate units. The substrate is cut by a laser beam aimed at the protecting film firstly and cut through the substrate along the peripheries of the scribe lines to singulate the substrate units. Therefore, the residue films of the protecting film on the substrate units can easily be removed. The contaminations of the substrate units by the sputtered particles and the melted protecting film during laser cutting can be eliminated. The shapes of the substrate units can be diverse.

### FIELD OF THE INVENTION

The present invention relates to fabrication technologies of semiconductor devices, especially to a method for singulating semiconductor devices by laser cutting a substrate.

### BACKGROUND OF THE INVENTION

In semiconductor fabrication, singulation of semiconductor devices is important. As shown in FIGS. 2, a wiring substrate 110 is usually used as a chip carrier where the substrate 110 is a substrate strip or a substrate panel including a plurality of array substrate units 111 corresponding to every semiconductor packages. After assembling, the substrate 110 is cut along the scribe lines 112 of the substrate 110 to form a plurality of individual semiconductor packages to achieve mass production with lower costs. As shown in FIG. 1, a chip 140 is normally disposed on the internal surface 113 of the substrate unit 111 to be a bare-die package or an encapsulated package. A plurality of external terminals 150 are disposed on the external surface 114 of the substrate unit 111 for external electrical connections. The existing method of cutting a substrate can be divided into cutting by a diamond blade or by a laser beam. However, when using a diamond blade to cut the substrate 110, the substrate 110 is easily broken and causing sharp edges during cutting processes. Furthermore, an additional grinding step is needed to smooth the cutting surfaces and misalignment issues may be encountered during cutting the substrate 110 in horizontal directions. Using a laser beam to cut the substrate 110 has been widely implemented due to easy direction control, high brightness, monochrome characteristics, easy space control and time control. Moreover, laser cutting is very flexible in its implementations such as materials, shapes, dimensions, and working environment, especially useful for automatic processing. The method of laser cutting can be divided into hot processes and cold processes. The hot process of laser cutting is to aim and focus a laser beam on the object such as the surface of the substrate 110. The high energy of the laser beam will rapidly heat up the substrate 110 to cut, melt, and evaporate the materials of the substrate 110. Since there is no physical contact of the laser head to the substrate 110, therefore, there is no friction between the laser head and the substrate 110 so that the cutting speed of a laser is faster without making any noises, moreover, the heat-impacted area of the substrate is limited.

However, as shown in FIG. 3, the substrate 110 is placed on a stage 160 for singulation, a laser beam emitted from a laser head 130 focuses on the internal surface 113 of the substrate 110 along the scribe lines 112 to cut through the substrate 110 where the high energy of the laser beam will melt the substrate 110 and create particles 116 which are re-disposed on the internal surface 113 of the substrate 110 leading to contaminations of the substrate units 111 on the internal surface 113 of the substrate 110 or contaminations of the chip 140. Furthermore, the heated particles 116 may melt on the substrate 110 or on the chip 140 to form rough surfaces which can not easily be removed by blowing nor washing leading to defects in electrical quality and in the appearance of the semiconductor packages.

As shown in FIG. 4, even changing the laser cutting surface from the scribe lines 112 on the internal surface 113 to the ones on the external surface 114 of the substrate 110, the laser beam emitted from a laser head 130 focuses on the scribe lines 112 on the external surface 114 of the substrate 110 to cut through the substrate 110 where the high energy of the laser head 130 will still melt the substrate 110 and create particles 116 which is sputtered on the external surface 114 of the substrate 110 leading to contaminations of the substrate units 111 on the external surface 114 of the substrate 110 or contaminations of the external terminals 115 leading to poor reliability of semiconductor packages. Furthermore, the deeper of the laser cutting depth, the worse the contaminations of the substrate 110. In order to avoid severe contaminations, cutting substrates by a laser can not widely be implemented in Mold Array Package, MAP, which has a large molding area where the implementations of laser cutting are limited for singulating semiconductor packages.

### SUMMARY OF THE INVENTION

The main purpose of the present invention is to provide a method for singulating semiconductor devices by laser cutting a substrate. It can solve conventional particle contaminations during laser cutting and to avoid the melted adhesive materials adhere to the substrate units to ensure good reliability of products. Furthermore, the residue films of the protecting film on the substrate after cutting can also easily be removed to enhance the singulation processes.

The second purpose of the present invention is to provide a method for singulating semiconductor devices to laser-cut a substrate into diverse shapes of the substrate units.

The third purpose of the present invention is to provide a method for singulating semiconductor devices to avoid particle contaminations on the substrate to expand the implementations of laser cutting in various semiconductor packages.

The fourth purpose of the present invention is to provide a method for singulating semiconductor devices to achieve accurate alignment between a protecting film and a substrate to ensure the patterned adhesive layer accurately adhere to the scribe lines of the substrate without any misalignment.

According to the present invention, a method for singulating semiconductor devices comprises the following steps. Firstly, a substrate is provided where the substrate has a plurality of substrate units and a plurality of scribe lines between the substrate units. Then, a protecting film is provided where the protecting film has an attaching surface with a patterned adhesive layer formed on the attaching surface corresponding to the scribe lines. Then, the attaching surface of the protecting film is attached to the substrate so that the patterned adhesive layer is aligned within and adheres to the scribe lines. Then, the substrate is cut by a laser beam where the laser beam is aimed at the protecting film and cut through the substrate along the peripheries of the scribe lines to separate the substrate units. Finally, the residue films of the protecting film are easily removed from the substrate units.

### DESCRIPTION OF THE DRAWINGS

FIG. 1 shows a cross-sectional view of a conventional semiconductor device.

FIG. 2 shows a top view of the external surface of a substrate including a plurality of substrate units in conventional semiconductor packages.

FIG. 3 shows the cross-sectional view of the conventional substrate during singulation by laser cutting from the internal surface of the substrate.

FIG. 4 shows the cross-sectional view of the conventional substrate during singulation by laser cutting from the external surface of the substrate.

FIGS. 5A to 5E show the cross-sectional views of a substrate during singulating processes according to the first embodiment of the present invention.

FIG. 6 shows the external surface of the substrate according to the first embodiment of the present invention.

FIG. 7 shows the attaching surface of a protecting film for the singulation according to the first embodiment of the present invention.

FIGS. 8A to 8E show the cross-sectional views of another substrate during singulating processes according to the second embodiment of the present invention.

FIGS. 9A to 9B show the diverse cut shapes of the substrate units by using the method according to the second embodiment of the present invention.

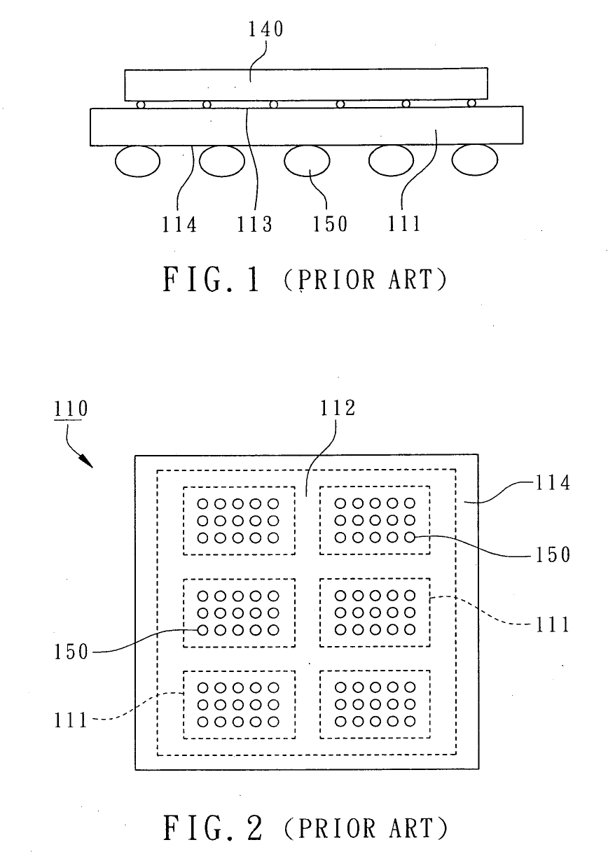

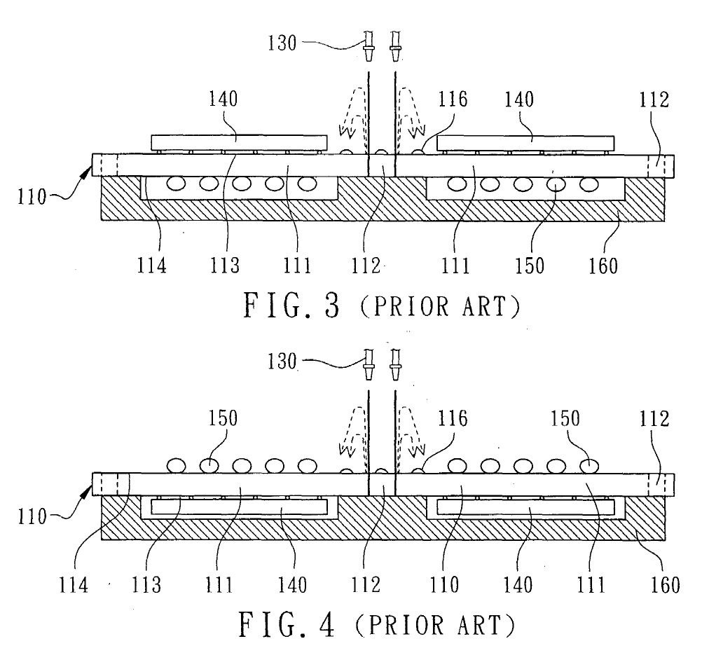

### DETAIL DESCRIPTION OF THE INVENTION

Please refer to the attached drawings, the present invention will be described by means of embodiments below.

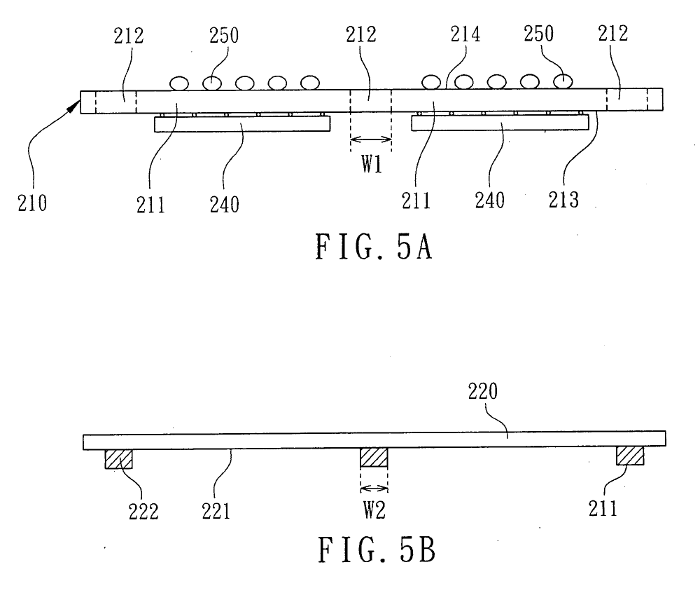

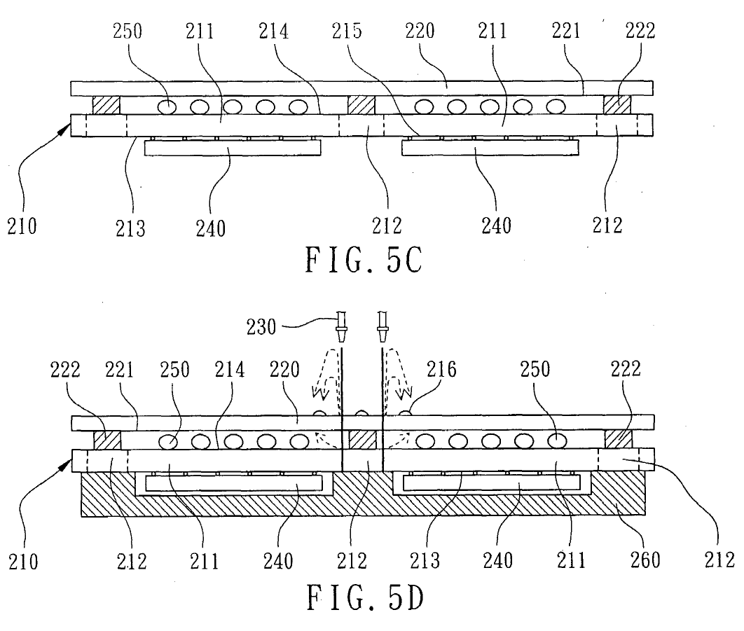

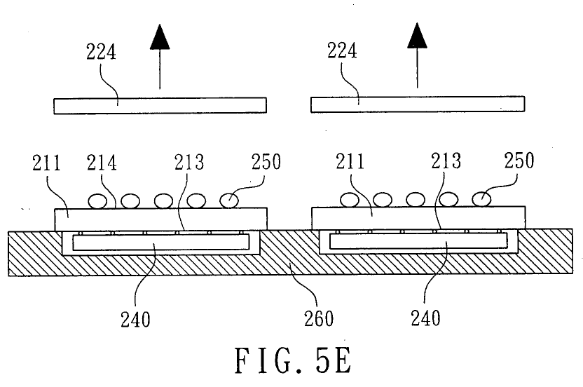

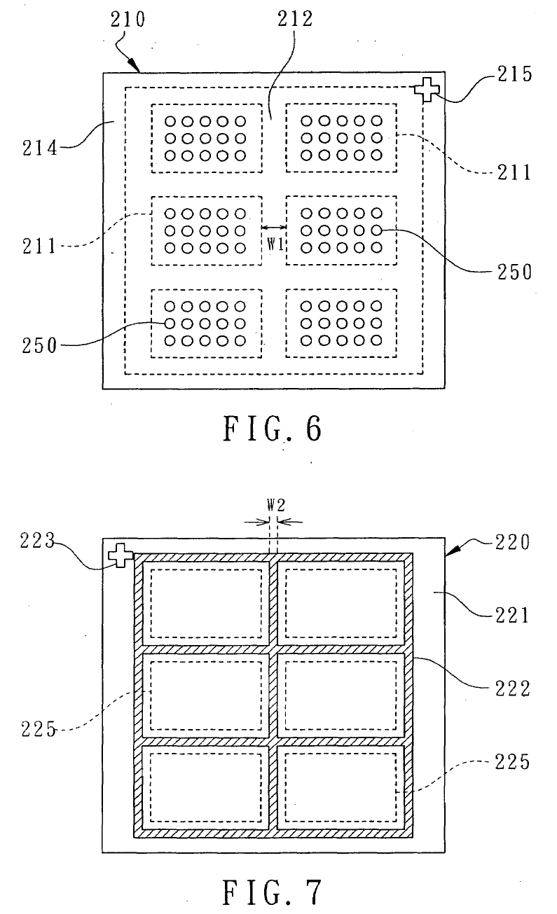

According to the first embodiment of the present invention, a method for singulating semiconductor devices comprises the following steps. Firstly, as shown in FIG. 5A and FIG. 6, a substrate 210 is provided where the substrate 210 has a plurality of substrate units 211 and a plurality of scribe lines 212 between the substrate units 211. The substrate 210 further has an internal surface 213 and an external surface 214. Each substrate unit 211 is used as a chip carrier where at least a chip 240 is attached to the internal surface 213 thereon. The substrate units 211 are arranged in an array, as shown in FIG. 6. Each substrate unit 211 has a plurality of traces, fingers, leads or vias (not shown in figures) for transmissions of electrical signals in the semiconductor device. In the present embodiment, semiconductor devices assembled from the substrate units 211 can be bare-die flip-chip packages or Ball Grid Array package. As shown in FIG. 5A, a plurality of external terminals 250 are bonded to the external pads, not shown in the figure, disposed on the external surface 214. In the present embodiment, the external terminals 250 include a plurality of solder balls disposed on the external surface 214 of the substrate 210. In different embodiments, solder paste, metal balls, metal plugs, or ACF conductive paste can be alternatives used as the external terminals 250 to replace the solder balls in the present invention. Furthermore, in the present embodiment, the chips 240 are electrically connected to the substrate 210 by flip-chip bonding to eliminate conventional wire-bonding and to form bare-die packages. As shown in FIG. 5A and FIG. 6, the scribe lines 212 has a first width W1 which is the distance between the edges of two adjacent substrate units.

Then, as shown in FIG. 5B and FIG. 7, a protecting film 220 is provided where the protecting film 220 has an attaching surface 221 with a patterned adhesive layer 222 thereon. The patterned adhesive layer 222 formed on the attaching surface 221 is patterned corresponding to the scribe lines 212 (as shown in FIG. 6). In the present invention, the materials and the physical properties of the patterned adhesive layer 222 are not limited such as photo-curing, thermal-setting, thermal-plastic with permanent or temporary adhesions. Unlimitedly, when attaching to the substrate 210, the patterned adhesive layer 222 can be half-cured or complete-cured. As shown in FIG. 5B and FIG. 7 again, the patterned adhesive layer 222 has a second width W2 where the second width W2 of the patterned adhesive layer 222 is smaller than the first width W1 of the scribe lines 212. As shown in FIG. 5C, a gap within the scribe lines 212 and out of the patterned adhesive layer 222 is formed for laser cutting after the protecting film 220 attached to the substrate 210.

Then, as shown in FIG. 5C again, the attaching surface 221 of the protecting film 220 is attached to the substrate 210 so that the patterned adhesive layer 222 is aligned within and adheres to the scribe lines 212. Preferably, the patterned adhesive layer 222 doesn't adhere to the substrate units 212, however, the protecting film 220 still can be secured with the substrate 210. In the present embedment, the external surface 214 of the substrate 210 faces to the protecting film 220 and the thickness of the patterned adhesive layer 222 is slightly greater than the heights of the external terminals 250 bonded on the external surface 214 so that the protecting film 220 will not extrude or shift from the substrate units 211 after attachment. The attaching forces can be evenly exerted on the patterned adhesive layer 222. However, the protecting film 220 is not limited in attached to the external surface 214 of the substrate 210. An alternative way is to face the internal surfaces 213 of the substrate 210 to the protecting film 220 which will be described in detail in the second embodiment. Of course, when the internal surface 213 of the substrate 210 faces the protecting film 222, the thickness of the patterned adhesive layer 222 is greater than the one of the extrusion on the internal surface 213 of the substrate 210, such as chips or encapsulants in semiconductor packages with small mold areas so that the protecting film 220 will not extrude or shift from the substrate units 211 after attachment. The attaching forces are evenly exerted on the patterned adhesive layer 222.

In the present embodiment, the substrate 210 has a first alignment mark 215 as shown in FIG. 6 and the protecting film 220 has a second alignment mark 223 as shown in FIG. 7. During attaching the protecting film 220, the second alignment mark 223 is aligned to the first alignment mark 215 so that the patterned adhesive layer 222 can be accurately aligned and attached to the scribe lines 212 or to the components located on top of the scribe lines 212 such as encapsulants of Mold Array Package, MAP, to achieve accurate alignment without shifting. As shown in FIG. 7, in the present embodiment, the patterns of the patterned adhesive layer 222 can be a mesh having a plurality of openings larger than the corresponding area 225 which have the same areas with the substrate units 211 as shown in FIG. 6. The patterned adhesive layer 222 can be formed on the protecting film 220 by screen printing, stencil printing or by pattern transferring.

Then, as shown in FIG. 5D, the substrate 210 is cut by a laser beam. The substrate 210 is placed on a stage 260 with a plurality of cavities to accommodate the chips 240. The laser beam is emitted from the laser head 230 and is aimed at the protecting film 222. The laser beam further cuts through the substrate 210 along the peripheries of the scribe lines 212 to separate the substrate units 211. To be more specific, the laser beam from the laser head 230 used to cut the substrate 210 cuts at the gap within the scribe lines 212 but out of the patterned adhesive layer 222 since the first width W1 of the scribe line 212 is larger than the second width W2 of the patterned adhesive layer, as shown in FIG. 5A and FIG. 5B. Therefore, the laser doesn't melt the patterned adhesive layer 222 to eliminate the contamination of the particles from the patterned adhesive layer 222 to the substrate units 211 of the substrate 210.

As shown in FIG. 5D again, the laser beam emitted from the laser head 230 cut the protecting film 220 prior to cutting the substrate 210 during the singulating processes. When the high-energy laser beam hits the surface of the protecting film 220, the particles 216 created by the melted protecting film 220 will melt and accumulate at the top surface of the protecting film 220, i.e., the other surface corresponding to the attaching surface 221 of the protecting film 220 without contaminating the substrate 210. When the laser beam reaches the substrate 210, the sputtered particles 216 will adhere to the attaching surface 221 or the patterned adhesive layer 22 without contaminating the external terminals 250 nor the external surface 214 of the substrate 210. The protecting film 220 serves as the absorption medium for the sputtered particles 216 during laser cutting the substrate 210. The conventional rough surface issues of the substrate units 211 due to laser cutting can be avoided.

Finally, as shown in FIG. 5E, the protecting film 220 is also singulated into a plurality of residue films 224 on the corresponding substrate units 211 during the laser cutting processes. The dimensions of the residue films 224 are corresponding to the ones of the substrate units 211 but not or slightly covered by the patterned adhesive layer 222 so that the residue films 224 of the protecting film 220 can easily be removed from the substrate units 211. To be more specific, after the singulation, the residue films 224 do not adhere to the substrate units 211. Therefore, according to the laser cutting method revealed in the present invention, the residue films 224 can easily be removed by tearing, air-blowing or other simple methods.

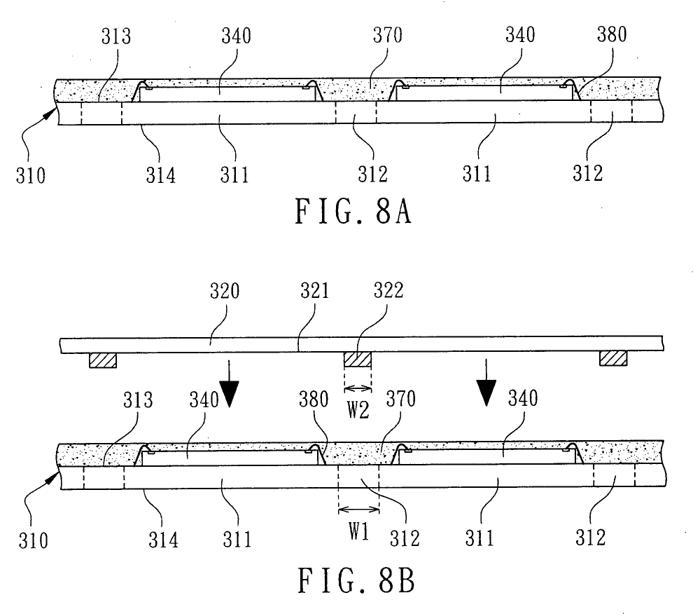

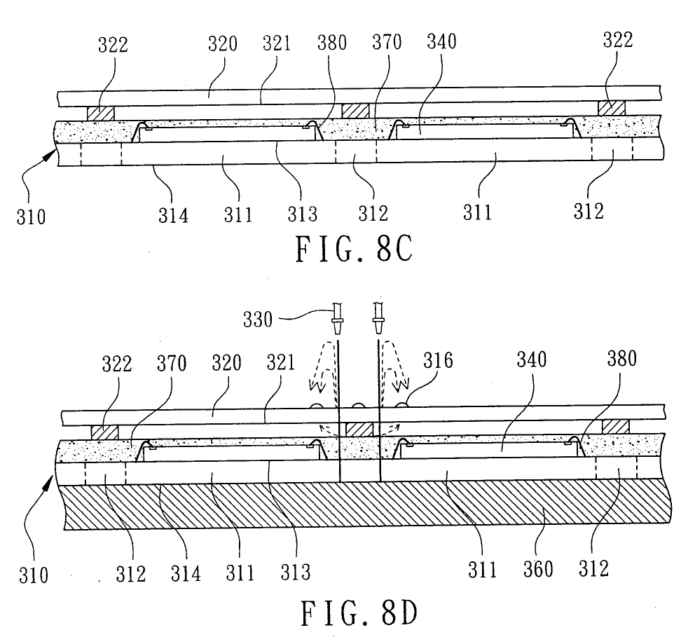

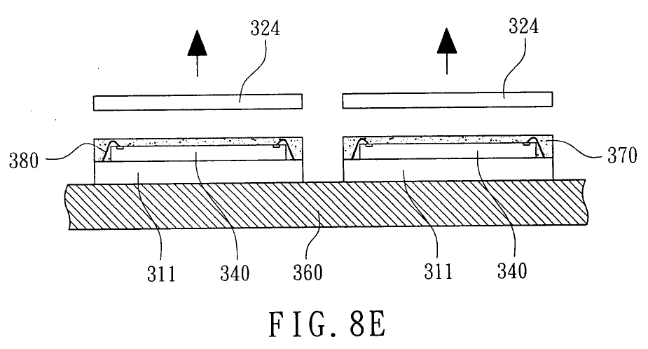

Another method of laser cutting a substrate according to the second embodiment of the present invention is shown in FIGS. 8A to 8E. Firstly, as shown in FIG. 8A, a substrate 310 is provided where the substrate 310 has a plurality of substrate units 311 and a plurality of scribe lines 312 between the substrate units 311. The substrate 310 has an internal surface 313 and an external surface 314 and each substrate unit 311 is carried with a chip 340 attached to the internal surface 313. The back surface of each chip 314 is attached to the internal surface 313 of the substrate 310 by a die-attaching material, not shown in the figure. The chip 340 is electrically connected to the corresponding substrate unit 311 by a plurality of bonding wires 380 formed by wire bonding. In the present embodiment, the semiconductor devices utilizing the substrate units 311 are Mold Array Packages, MAP, such as fully-mold LGD or BGA or all kinds of memory cards. An encapsulant 370 is formed over the internal surface 313 of the substrate 310 to encapsulate the chip 340 and the bonding wires 380 to provide appropriate protections and to prevent electrical short and any possible contaminations. The encapsualant 370 also covers the scribe lines 312 in addition to the substrate units 311.

Then, as shown in FIG. 8B, a protecting film 320 is provided where the protecting film 320 has an attaching surface 321. A patterned adhesive layer 322 is formed on the attaching surface 321 and has a pattern corresponding to the scribe lines 312. To be more specific, as shown in FIG. 8B again, the scribe lines 312 has a first width W1′ and the patterned adhesive layer 322 corresponding to the scribe lines 312 has a second width W2′. The second width W2′ is smaller than the first width W1′ to form a gap for laser cutting.

Then, as shown in FIG. 8C, the attaching surface 321 of the protecting film 320 is attached to the encapsulant 370 on the scribe lines 312. To be more specific, the surface of the encapsulant 370 is flat. The thickness of the patterned adhesive layer 322 can be reduced but still maintain a tiny gap to adhere the particles 316 sputtered from the protecting film 320 during laser cutting processes without contaminating the encapsulant 370.

Then, as shown in FIG. 8D, the substrate 310 is cut by a laser beam. The substrate 310 is placed on a stage 360. A laser beam is emitted from the laser head 330 and is aimed at the protecting film 320. The laser beam cuts through the substrate 310 along the peripheries of the scribe lines 312 to separate the substrate units 311. To be more specific, the laser beam can cut at the gap within the scribe lines 312 and out of the pattern adhesive layer 322 since the first width W1′ of the scribe lines 312 is larger than the second width W2′ of the patterned adhesive layer 322, as shown in FIG. 8B. Therefore, the patterned adhesive layer 322 will not melt by the laser beam to eliminate any contaminations.

Furthermore, as shown in FIG. 8D, during laser cutting processes, the laser beam cuts through the protecting film 320 firstly, then through the encapsulant 370, then through the substrate 310 from the internal surface 313 to the external surface 314 so that the sputtered particles 316 will adhere to the protecting film 320 or to the patterned adhesive layer 322 to eliminate surface contaminations of the encapsulant 370 leading to cleaner surface of the encapsulant 370. Even the cutting depth of the laser increases, the contaminations will not increase so that the implementations of the method according to the invention can be expanded in various semiconductor devices.

Finally, as shown in FIG. 8E, the residue films 324 of the protecting film 320 on the substrate units 310 are removed. After laser cutting, the residue films 324 on the substrate units 310 are free from adhesive so that the residue films 324 can easily be removed from the corresponding singulated semiconductor devices without contaminations due to the laser cutting processes.

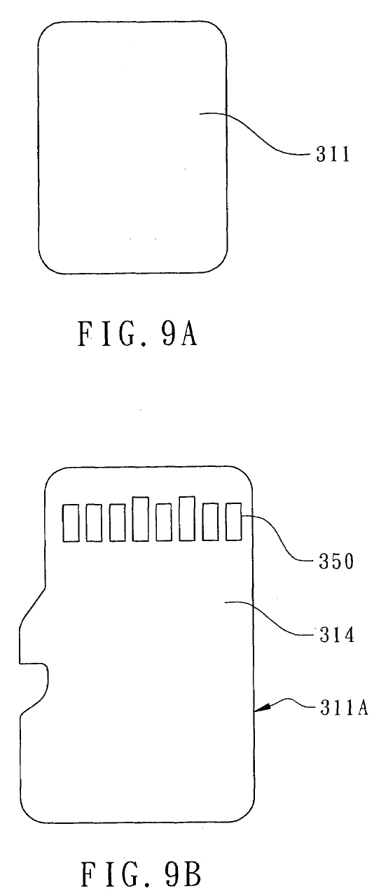

Furthermore, the shapes of the semiconductor devices formed by the laser cutting method according to the present invention are not limited. The shapes of the substrate units 311 of the substrate 310 can be any shapes such as a memory card with arc corners, LGA or BGA packages, as shown in FIG. 9A. The laser-cut substrate units 311A can further be implemented in micro SD (Secure Digital) card as shown in FIG. 9B. A plurality of external terminals 350 such as gold fingers can be disposed on the external surface 314 of the substrate unit 311A for external electrical connections.

In summary, the singulation method by laser cutting according to the present invention can be implemented in cutting any shapes of the substrate units, in avoiding particles adhering to the substrate due to laser cutting without affecting the appearances and the reliability of the semiconductor packages. Furthermore, the residue films of the protecting film can easily be removed to enhance the substrate singulation processes.

The above description of embodiments of this invention is intended to be illustrative and not limiting. Other embodiments of this invention will be obvious to those skilled in the art in view of the above disclosure.

What is claimed is:

1. A method for singulating semiconductor devices, primarily comprising the steps of:
providing a substrate having a plurality of substrate units and a plurality of scribe lines between the substrate units;
providing a protecting film having an attaching surface with a patterned adhesive layer formed on the attaching surface corresponding to the scribe lines;
attaching the attaching surface of the protecting film to the substrate so that the patterned adhesive layer is aligned within and adheres to the corresponding scribe lines;
cutting the substrate by a laser beam aimed at the protecting film and cutting through the substrate along the peripheries of the scribe lines to separate the substrate units; and
removing the residue films of the protecting film on the substrate units.

2. The method as claimed in claim 1, wherein the residue films are the same as the substrate units in dimensions without covering by the patterned adhesive layer.

3. The method as claimed in claim 1, wherein the scribe lines have a first width and the patterned adhesive layer has a second width wherein the second width is smaller than the first width to form a gap for laser cutting.

4. The method as claimed in claim 3, wherein the laser beam cuts at the gap within the scribe lines and out of the patterned adhesive layer.

5. The method as claimed in claim 1, wherein the substrate has an internal surface and an external surface, and wherein each substrate unit is carried with at least a chip attached to the internal surface.

6. The method as claimed in claim 5, wherein an encapsulant is formed over the internal surface of the substrate to encapsulate the substrate units and the scribe lines.

7. The method as claimed in claim 5, wherein the internal surface of the substrate faces the protecting film during the step of attaching the protecting film.

8. The method as claimed in claim 5, wherein the external surface of the substrate faces the protecting film during the step of attaching the protecting film.

9. The method as claimed in claim 8, wherein the external surface of each substrate unit has a plurality of external terminals, and wherein the thickness of the patterned adhesive layer is slightly greater than the height of the external terminals.

10. The method as claimed in claim 1, wherein the substrate has a first alignment mark and the protecting film has a second alignment mark wherein the second alignment mark is aligned to the first alignment mark during the step of attaching the protecting film.

11. The method as claimed in claim 1, wherein the patterned adhesive layer is a mesh having a plurality of openings larger than the substrate units.
